(19) United States
(12) Patent Application Publication
(10) Pub. No.: US 2007/0175392 A1
(43) Pub. Date: Aug. 2, 2007

(54) MULTIPLE PRECURSOR DISPENSING APPARATUS

(75) Inventor: Dmitry Znamensky, West Chester, PA (US)

Correspondence Address: AIR LIQUIDE;Intellectual Property, 2700 POST OAK BOULEVARD, SUITE 1800, HOUSTON, TX, 77056, US

(73) Assignee: AMERICAN AIR LIQUIDE, INC., Houston, TX (US)

(21) Appl. No.: 11/621,419

(22) Filed: Jan. 9, 2007

Related U.S. Application Data
(60) Provisional application No. 60/762,987, filed on Jan. 27, 2006.

(51) Int. Cl. C23C 16/00; H01L 21/306; B05C 11/00

(52) U.S. Cl. 118/715; 156/345.29; 118/688; 156/345.24

(57) ABSTRACT

An apparatus for dispensing multiple precursors to a manufacturing tool includes a fluidic manifold having a plurality of interconnected sub-manifolds, a plurality of tanks, each tank containing a different precursor, and wherein each of the sub-manifolds is connected to one of the tanks. A system for dispensing multiple precursors to a manufacturing tool includes a multiple precursor dispenser having a fluidic manifold and a plurality of tanks, each tank containing a different precursor and connected to a different sub-manifold of the fluidic manifold, the sub-manifolds being interconnected, a manufacturing tool fluidic processor having a plurality of canisters, each canister containing a different precursor, wherein a first dispenser tank communicates with a first tool canister having the same precursor, and wherein a second dispenser tank communicates with a second tool canister having the same precursor. Related methods are also described herein.

### CROSS-REFERENCE TO RELATED APPLICATIONS

The present application claims the benefit of U.S. Provisional Application Ser. No. 60/762,987, filed Jan. 27, 2006, entitled Multi-Precursor Dispensing System and the Refilling Control Method, which is hereby incorporated herein by reference.

### STATEMENT REGARDING FEDERALLY SPONSORED RESEARCH OR DEVELOPMENT

Not applicable

### BACKGROUND

In the process chemical delivery industry, complex chemical dispensing systems and methods are used to deliver ultra pure, reactive and often toxic liquid chemical product, or precursors, to manufacturing tools (reactors) such as thin film deposition tools. Tools for delivering a thin film to a solid substrate are used in the manufacture of semiconductors, optical equipment and products, and chemical resistant coatings, for example. In particular, various liquid precursors are applied to advanced semiconductor electronics using a chemical vapor deposition (CVD) process. The chemical dispensing system delivers mixtures including the liquid precursor to the reactor in the deposition tool for application to the semiconductor device. Exemplary precursor deposition methods include metal-organic CVD, atomic layer CVD, and those for high-k gate dielectrics using metal gates and various barrier layers.

The liquid chemical product, or precursor, demanded by a manufacturing tool is held in a canister. Such canisters may also be supplied by larger, separate tanks, to facilitate continuous refilling of the canisters and minimize interruption of the manufacturing process. Each canister requires a controller and gas/liquid manifold to manage the precursor flow, with the entire apparatus being housed in a cabinet. The special cabinet for the precursor canister is located in the clean room adjacent the reactor, where space is very critical and limited. For a single precursor deposition process, this arrangement is entirely acceptable.

However, the demands of the industry are changing. Progressively, more liquid chemical product is being managed and delivered by chemical delivery systems as manufacturer demand for such product increases. Additionally, and more significantly, the industry is developing multi-compound laminates for the deposition process. To deposit multi-compound laminates, two, three, foul or more precursors may need to be supplied to a single tool simultaneously. Each of the multiple precursors requires a separate delivery apparatus, including a fluidic manifold or processor for managing each precursor and possibly special cabinets for containing each precursor and its fluidic processor. The additional delivery apparatus increases the system's footprint and cost. It is impractical and undesirable to place multiple precursor fluidic processors or cabinets inside the clean room adjacent the reactor—the critical space available in the clean room cannot accommodate the increased footprint of the multiple precursor processors. It is also impractical and undesirable to place the precursor processors apart from the clean room, as doing so drastically reduces the flow rates coming from the canisters. The canisters have a relatively small volume (e.g, 1 liter), and cannot provide the proper flow rates needed by the tool if there is a significant distance between the canister and the tool. Therefore, the needs of the industry, particularly the need to supply multiple precursors to a single tool, are pushing the limits of current chemical delivery systems

### SUMMARY

In an embodiment of the invention, an apparatus for dispensing multiple precursors to a manufacturing tool includes a fluidic manifold having a plurality of interconnected sub-manifolds; a plurality of tanks, each tank containing a different precursor; and wherein each of the sub-manifolds is connected to one of the tanks. In another embodiment of the invention, a method of dispensing multiple precursors to a manufacturing tool is described.

In a further embodiment of the invention, a system for dispensing multiple precursors to a manufacturing tool includes a multiple precursor dispenser having a fluidic manifold and a plurality of tanks, each tank containing a different precursor and connected to a different sub-manifold of the fluidic manifold, the sub-manifolds being interconnected; a manufacturing tool fluidic processor having a plurality of canisters, each canister containing a different precursor; wherein a first dispenser tank communicates with a first tool canister having the same precursor; and wherein a second dispenser tank communicates with a second tool canister having the same precursor. In another embodiment, a related system method is described

### BRIEF DESCRIPTION OF THE DRAWINGS

For a more detailed description of preferred embodiments of the present invention, reference will now be made to the accompanying drawings, wherein:

FIGS. 1A and 1B are schematic illustrations of a multiple precursor dispenser in accordance with an embodiment of the invention, with FIG. 1A depicting the fluidic manifold portion of the dispenser and FIG. 1B depicting the chemical tanks portion of the dispenser;

FIG. 2 is a schematic illustration of an auxiliary unit in accordance with an embodiment of the invention;

FIG. 3 is a schematic illustration of a manufacturing tool fluidic processor in accordance with an embodiment of the invention; and

FIGS. 4A-4D are schematic illustrations of an alternative embodiment of a complete system in accordance with an embodiment of the invention, including the multiple precursor dispenser of FIGS. 1A and 1B, the auxiliary unit of FIG. 2, and the manufacturing tool fluidic processor of FIG. 3.

### DESCRIPTION OF PREFERRED EMBODIMENTS

Certain terms are used throughout the following description and claims to refer to particular system components. This document does not intend to distinguish between components that differ in name but not function.

In the following discussion and in the claims, the terms “including” and “comprising” are used in an open-ended fashion, and thus should be interpreted to mean “including, but not limited to . . . ”. Also, the term “precursor” is used herein to mean a reactive substance that, through the deposition process, becomes part of the layer applied to the semiconductor or other manufactured product. A precursor is a reactive and toxic compound having moderate or low volatility and being highly sensitive to micro-concentrations of oxygen and moisture. The term “precursor” is also used more generally herein to refer to the chemical products stored, delivered and used in the deposition processes described herein. Various components described herein are connected by or communicate through conduits or lines, and it is to be understood that the terms “conduit” or “line” may include pipes, tubes, or other means for transporting gases and their liquid phase counterparts.

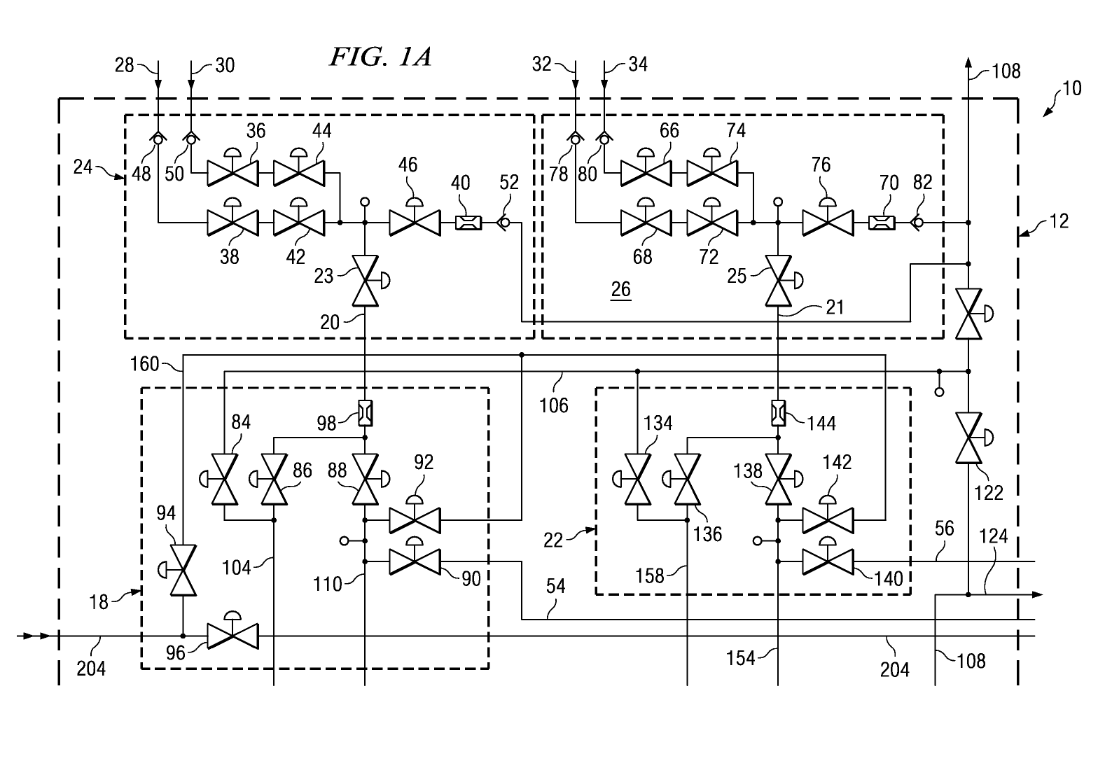

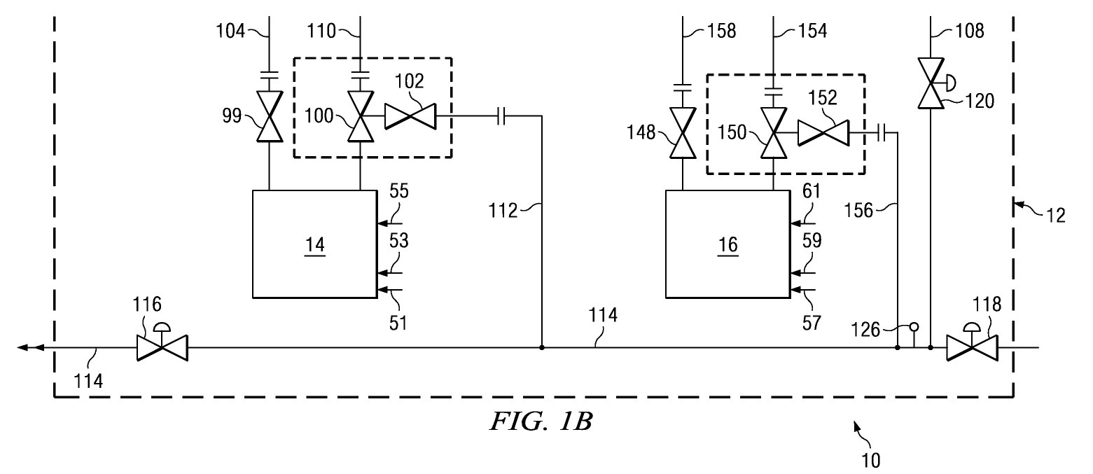

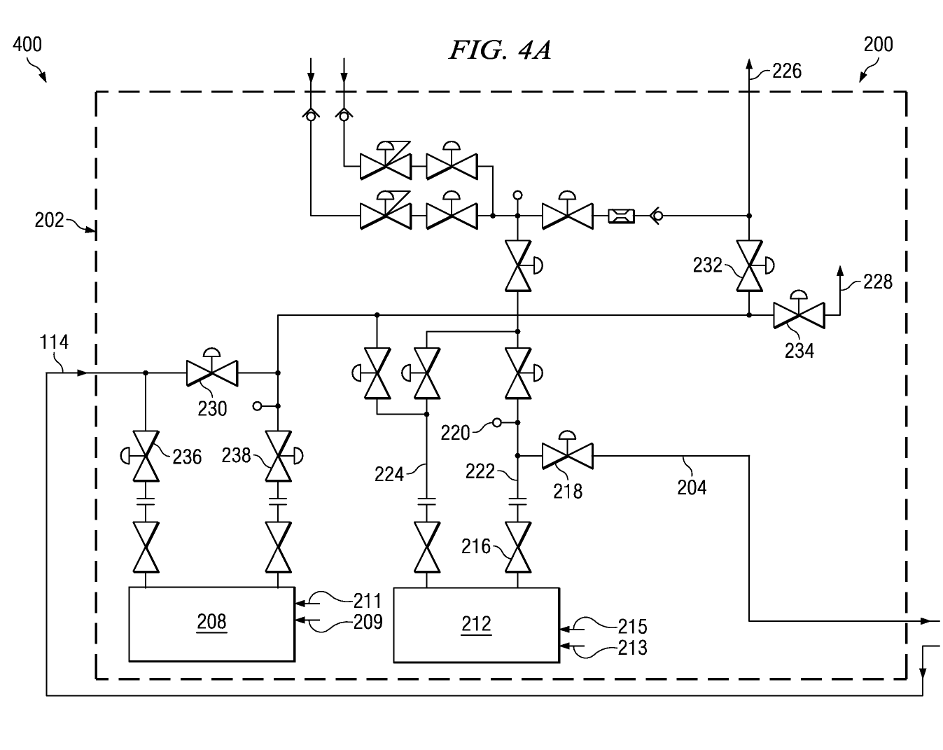

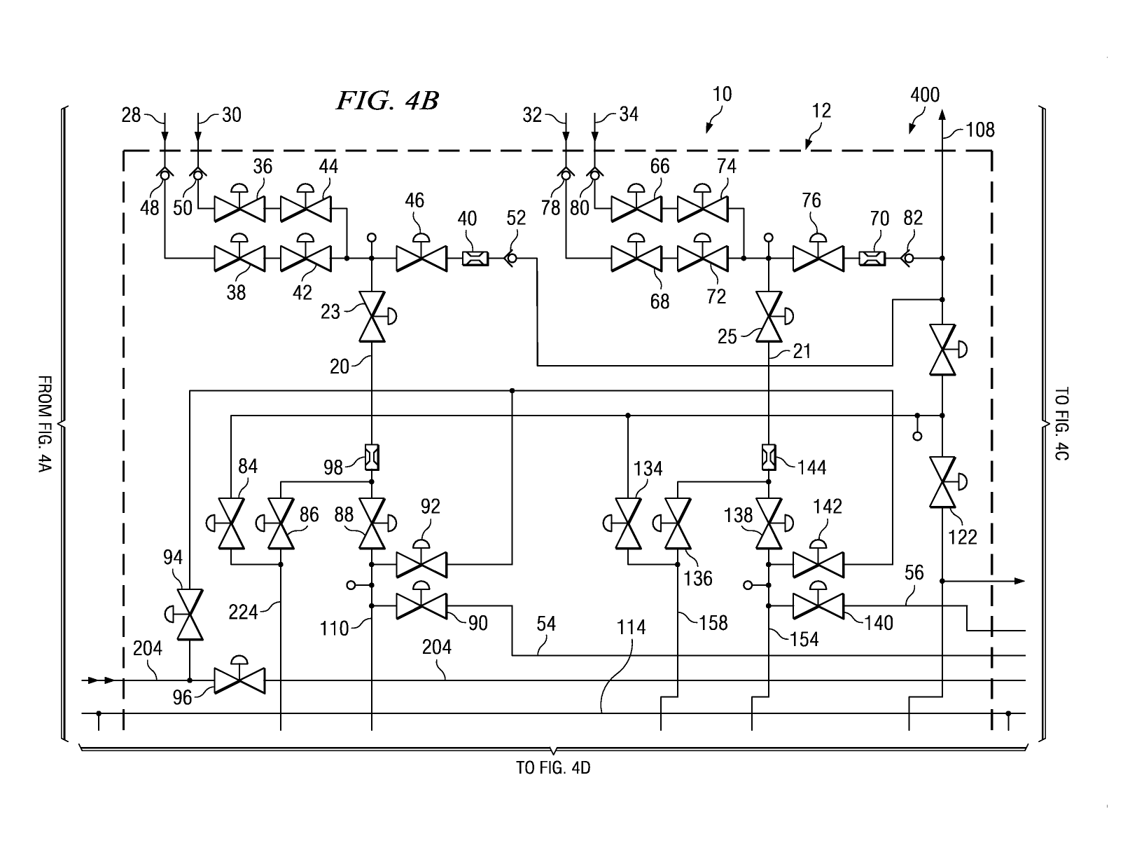

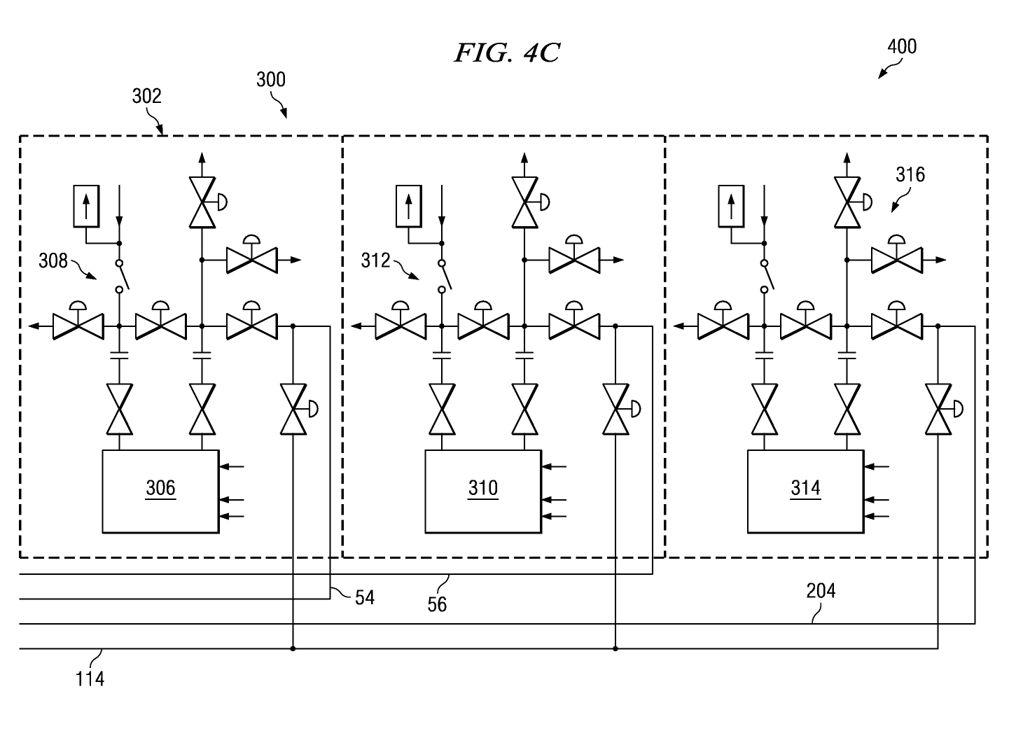

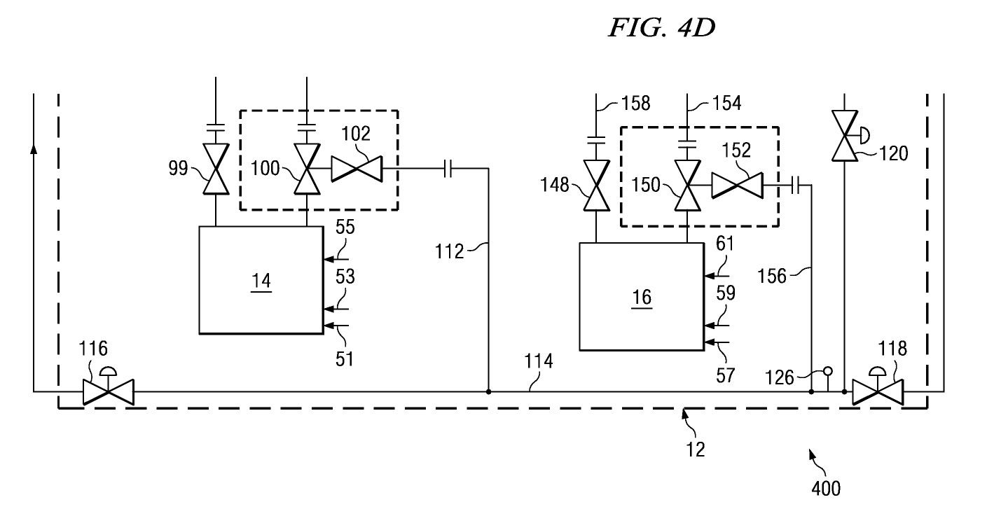

With reference to FIGS. 1A and 1B, a bulk multiple precursor processor or multiple dispenser 10 is shown in schematic form. The multiple dispenser 10 is divided into the fluidic manifold portion (FIG. 1A) and the chemicals tanks portion (FIG. 1B) to increase visual clarity of the schematic drawings. The multiple dispenser 10 is capable of handling a number of various precursors simultaneously. An exemplary dispenser may handle two to five precursors, for example. In some embodiments, the dispenser further handles a solvent, more precursors, or other chemical products. The precursors, because of their reactive nature, require reliable and contamination-free delivery means to the point of use. The multiple dispenser 10 may be used in a high purity liquid delivery system, an exemplary embodiment of such a system described herein with reference to FIG. 4A-4D.

The multiple dispenser 10 includes an enclosure 12 housing a first bulk source canister or mother tank 14 and a second bulk source canister or mother tank 16, shown in FIG. 1B. The first mother tank 14 contains a first precursor and the second mother tank 16 contains a second precursor. The dispenser 10 may include additional tanks depending on the number of different precursors required by the manufacturing process. The mother tanks 14, 16 are constructed consistent with the teachings herein and to the knowledge of one having ordinary skill in the art, to contain precursor materials. The mother tanks are also of a suitable size for the processes described herein, for example, in the range of 15-20 gallons.

The first mother tank 14 is connected to a first chemical block or precursor sub-manifold 18 and the second mother tank 16 is connected to a second chemical block or precursor sub-manifold 22, as best shown in FIG. 1A. The chemical block 18 is dedicated to the mother tank 14 and passes the liquid product from the mother tank 14 into a process line or conduit 54. Likewise, the chemical block 22 is dedicated to the mother tank 16 and passes the liquid product from the mother tank 16 into a process line 56. The chemical blocks 18, 22 further serve to perform necessary fluid switches during various maintenance processes, such as gas pressurization/de-pressurization, gas and vacuum purge, solvent flush, and other processes consistent with the teachings herein.

With reference to FIG. 1A, the first mother tank 14 is also connected to a first gas block or sub-manifold 24 and the second mother tank 16 is connected to a second gas block or sub-manifold 26. The gas blocks 24, 26 provide pressurizing gas or gases to the mother tanks on an intermittent basis when needed, and maintain the precise setting for the gas pressure during the chemical product delivery from the mother tanks. Each of the chemical blocks 18, 22 and the gas blocks 24, 26 include a series of pressure regulators, pressure sensors, check valves, shut-off valves, orifices and other such devices shown schematically in FIG. 1, and may be collectively referred to as the dispenser fluidic manifold. Some of these devices are described more fully below. However, some of these devices are not described in detail as such devices are known to one having ordinary skill in the art and their description does not benefit a clear understanding of the embodiments of the invention described herein. Further, various combinations of pressure regulators, valves and orifices may be used with the embodiments of the present invention described herein. The present invention should not be limited to the combinations of such devices described herein and persons of ordinary skill in the art will appreciate that the present invention includes other combinations consistent with the teachings herein.

Still referring to FIG. 1A, regulated and filtered gas lines 28, 30 are connected to the gas block 24. The gas block 24 further includes pressure regulators 36, 38, release orifice 40, shut-off valves 42, 44, 46, and check valves 48, 50, 52. The process pressure in mother tank 14 is set individually and independently by the pressure regulators 36, 38 and the release orifice 40, and is automatically balanced by the shut-off valves 48, 50, 52. Alternatively, the orifice 40 may be replaced by a metering valve or a mass-flow-controller depending on the range and the precision of the set pressure required in the mother tank. The check valves 48, 50 isolate the supply gas lines 28, 30, respectively, from any potential contamination with traces of the product liquids should a massive component failure occur downstream in the gas block 24. The check valve 52 prevents possible contamination from the venting flows coming from the downstream chemical block 18.

Similarly, gas lines 32, 34 are connected to the gas block 26, which includes devices identical to those described with regard to the gas block 24. Specifically, the gas block 26 further includes pressure regulators 66, 68, release orifice 70, shut-off valves 72, 74, 76, and check valves 78, 80, 82. These series of devices operate identically to those comparable devices of the gas block 24. Further gas blocks consistent with those described herein may be included in the manifold 12 depending on the number of mother tanks included with the multiple dispenser 10.

Still referring to FIG. 1A, the gas block 24 is connected to the chemical block 18 via a conduit 20 having valve 23. The chemical block 18 further includes a grouping of valves 84, 86, 88, 90, 92, 94, 96 and an orifice 98. Disposed between the chemical block 18 and the mother tank 14 are a group of valves 99, 100, 102, as shown in FIG. 1B. The product liquid in the mother tank 14 is individually pressurized by the gas block 24 through a line 104 having normally open valves 86, 99 while the valves 84, 88 are normally closed. The valve 84 allows pressure relief of the line 104 by connecting the line 104 to a line 106, which then connects to a vent line 108. The product liquid in the mother tank 14 is withdrawn through an exit line 110 with the valve 100 open and the valve 102 closed, and further out through the open valve 90 into the process line 54. During withdrawal, the valves 88, 92 are closed.

At times, the mother tank 14 nears empty of the product liquid. The near-empty status is detected by a liquid level sensor represented schematically at sensor indicator 51. The actual sensor used includes external or internal sensors, and continuous or discrete sensors. Other liquid level sensors are known to one skilled in the art and are consistent with the teachings herein. The tank 14 may further include sensors 53, 55. With this arrangement of sensors 51, 53, 55, sensor 53 acts as a “LOW” sensor to indicate that the tank 14 may be changed out or refilled, but it does not need to be done immediately. If necessary, the tool's process may be completed, with a small precursor supply remaining in the tank 14. Sensor 51 will act as a “LOW-LOW” sensor to indicate that the tool's process must be stopped because the tank 14 does not contain an adequate precursor supply. Sensor 55 will act as a “HIGH” sensor to indicate that the tank 14 is full. The mother tank 16 includes a similar arrangement of sensors, including LOW-LOW sensor 57, LOW sensor 59 and HIGH sensor 61.

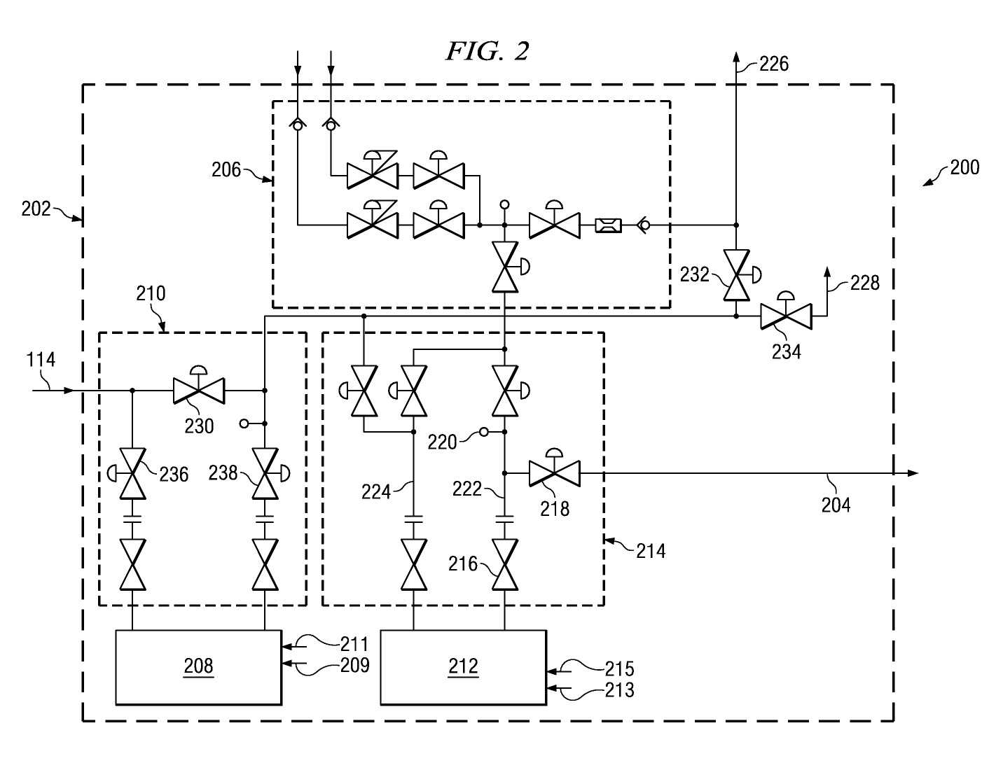

When it is time to refill and/or replace the mother tank 14, a change-over procedure occurs wherein the tank is removed from the chemical block 18. Opening the system to ambient conditions exposes reactive precursor remnants in the system to atmospheric components, most notably oxygen and moisture. Therefore, the remnants must be purged from the lines before opening the system. Most purging can be accomplished using gases and/or a vacuum. For those precursor remnants not removed by these methods, a solvent is used to sufficiently flush the lines. Certain parts of the chemical block 18 exposed to the reactive precursor are flushed with an appropriate solvent through the valve 92 while the valves 98, 100 are closed, and further through the open valve 102 into an exit line 112 leading to a waste line 114. The solvent flush is supported by the solvent tank and manifold, described and shown in more detail elsewhere herein. The waste line 114 is also able to communicate with the vent line 108. The waste line 114 further includes valves 116, 118, and the vent line 108 includes a valve 120. While the valve 116 is open, and the valves 118, 120 are closed, the waste travels to a waste tank (shown in FIGS. 2 and 4A, and described in further detail elsewhere herein). Alternatively, a purge gas is inserted into the chemical block 18 through the valve 88 and into the valve 102, and the waste travels to the waste tank or the vent line 108. If the waste is directed to the vent line 108 through the open valve 120, the waste may be directed to a vacuum line 124 by closing a valve 122. A residual pressure during these evacuation processes is monitored by a pressure sensor 126. During the mother tank 14 change-over, while the tank is unattached to the chemical block 18, an inert gas bleeding is maintained through the open valves 86, 88. The orifice 98 limits the bleeding gas flow to a desired safe flow rate.

Referring to FIGS. 1A and 1B, the arrangement of the second gas block 26, the second chemical block 22, and the second mother tank 16 is substantially similar to the arrangement of the first gas block 24, the first chemical block 18 and the first mother tank 14 previously described. More specifically, the gas block 26 is connected to the chemical block 22 via a conduit 21 having valve 25. The chemical block 22 further includes a grouping of valves 134, 136, 138, 140, 142 and an orifice 144. Disposed between the chemical block 22 and the mother tank 16 are a group of valves 148, 150, 152. The product liquid in the mother tank 16 is individually pressurized by the gas block 26 as previously described. The product liquid in the mother tank 16 is withdrawn through an exit line 154 and into the process line 56. A line 158 connects to the shared line 106, which then connects to the shared vent line 108. The shared line 106 allows the various sub-manifolds of the fluidic processor 10 to interconnect and communicate with a single, common vent line 108. Additional sub-manifolds associated with additional mother tanks may connect to the shared line 106 in the same manner and therefore also share use of the common vent line 108.

The change-over and line evacuation procedures may be repeated for the mother tank 16 as previously described with respect to the mother tank 14, and any additional mother tanks included with the dispenser 10. An exit line 156 carries waste from the mother tank 16 to the previously described shared waste line 114. The shared waste line 114 communicates with other parts of the dispenser 10 as before, and provides a common line to exhaust waste from any of the various interconnected chemical sub-manifolds referenced herein.

In some embodiments of the fluidic processor 10, the gas blocks 24, 26 may be consolidated into a single, shared gas block that supports the multiple chemical blocks. Referring to FIG. 1A, such a common gas block would appear similar to the gas block 24, except that most of the gas block 26 is eliminated and the line 21 is connected from above the valve 25 to the line 20 above the valve 23. If the fluidic processor 10 is to supply further precursors, the gas supply lines for the chemical blocks will connect to the main gas supply line of the common gas block in this manner. The common gas block provides a shared gas pressurizing sub-system for the processor 10.

Referring now to FIG. 2, an auxiliary module or unit 200 is shown schematically. The auxiliary module 200 is contained in a cabinet 202 placed at a distance from the dispenser 10, or, alternatively, the unit 200 is housed in the same enclosure or cabinet with the dispenser 10. The auxiliary unit 200 communicates with the dispenser 10 via a solvent exit line 204. Generally, the auxiliary unit 200 includes a gas block 206, a waste tank 208 having an associated waste tank sub-manifold 210, and a solvent tank 212 having an associated solvent tank sub-manifold 214. The gas block 206 has the same general design and function as the previously described gas blocks 24, 26. Therefore, it is not necessary to describe the gas block 206 in detail except where necessary to fully describe the independent features of the auxiliary unit 200. One of the functions of the auxiliary unit 200 is to support the previously mentioned solvent flush and waste features of the dispenser 10.

On demand, the solvent in the solvent tank 212 is forced into the solvent supply line 204 through valves 216, 218 by gases initiated in the gas block 206. The solvent travels through the supply line 204 to the common solvent supply line 204 of the dispenser 10 (FIGS. 1A and 4B) where the solvent may then travel through the valve 94 and into a shared dispenser solvent line 160 or through the valve 96 and into a tool solvent supply line 204. Thus, the common solvent supply line 204 allows the auxiliary unit 200 to support the dispenser 110 and the tool's fluidic processor 300. In the dispenser 10, the shared line 160 supplies all of the dispenser's chemical blocks.

The liquid solvent pressure is monitored by a pressure sensor 220. When the solvent tank 212 nears empty, as detected by LOW level sensor 215 and LOW-LOW level sensor 213 consistent with the teachings herein, it is changed out similarly to the change-over procedures previously described. The liquid leg of the solvent tank sub-manifold 214, generally shown with reference to a liquid line 222, is purged with a cleaning gas and evacuated before the solvent tank 212 is disconnected. The liquid leg and the gas leg, generally shown with reference to a gas line 224, are both bled with inert gas while the solvent tank 212 is disconnected. After a new solvent tank is attached and before any of the tank valves are opened, both legs are vacuum-purged at line 228 in order to rid the lines of traces of atmospheric contaminants.

The common waste line 114 is used to communicate waste liquids, such as flushed solvent, product chemicals, or a combination of both, from the multiple dispenser 10 and the deposition tool to the waste tank 208. A vent line 226 is used to vent the waste and purge gases from the dispenser and tool by opening the valves 118, 116 of the dispenser 10 (FIGS. 1B and 4D) and valves 230, 232 of the auxiliary unit 200 (FIGS. 2 and 4A) while closing valves 234, 236, 238 of the auxiliary unit. Thus, a common vacuum sub-system is shared between the interconnected dispenser module, tool module, and auxiliary module. When desired, the waste line 114 is evacuated through the open valves 230, 2.34 and a vacuum line 228 while the valves 232, 236, 238 are closed.

The various parts and operations of the dispenser 10 and the auxiliary unit 200 are controlled by a controller. The controller is not specifically shown or described because such a controller, adaptable for use with the various embodiments described herein, is widely available in the industry. The controller is configured to control each tank-manifold combination (for example, the mother tank 14 and the chemical block 18/gas block 24, or the solvent tank 212 and the manifold 214/gas block 206) independently of the other tank-manifold combinations. Thus, each precursor is managed and distributed independently of the other precursors, and the entire process of providing the various precursors to a manufacturing tool is flexible. For example, one precursor may be supplied at a time, or multiple precursors at a time. Further, one or more mother tanks may be changed out while other mother tanks are supplying precursor material.

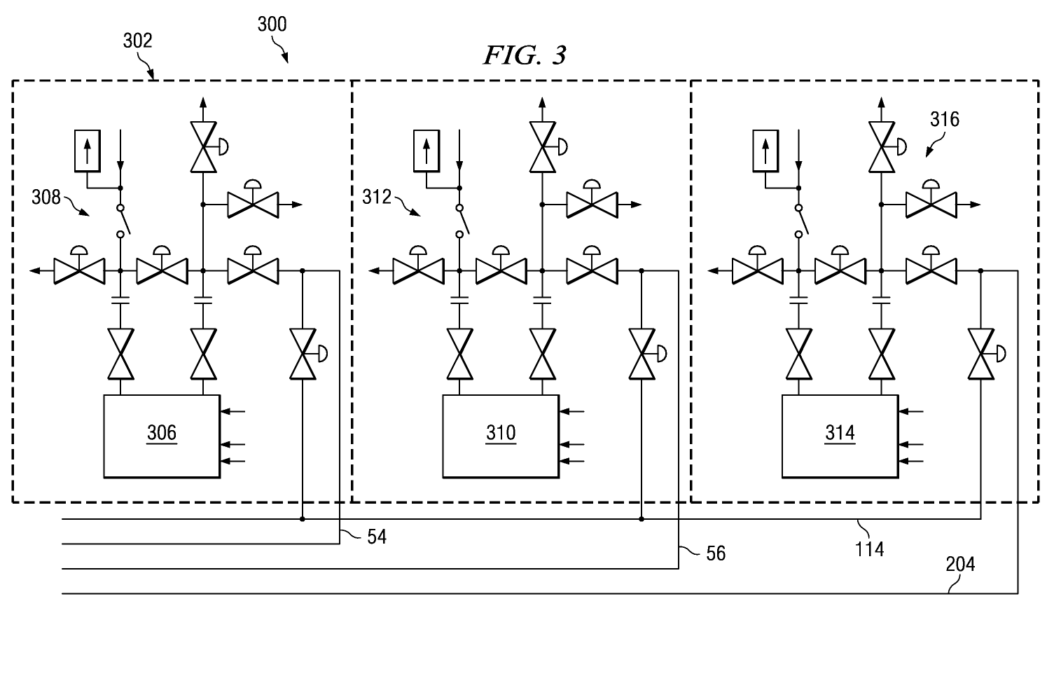

Referring now to FIG. 3, a chemical supply system or fluidic processor 300 for a deposition or manufacturing tool is shown schematically. The fluidic processor 300 includes a tool enclosure 302, which may be one or more manufacturing or fabrication plants, for example. The fluid processor 300 further includes a first day tank 306 having an associated chemical manifold 308, a second day tank 310 having an associated chemical manifold 312, and a solvent day tank 314 having an associated chemical manifold 316. The processor 300 may include further sets of day tanks and chemical manifolds as needed to satisfy the manufacturing process and its required number of precursors. The tanks 306, 310, 314 are constructed consistent with the teachings herein, including other tanks described herein. The tanks 306, 310, 314 may be various sizes, including, for example, 20 or 30 times smaller than the mothers tanks 14, 16, such as less than two liters. The mother tanks are much larger than the day tanks, therefore the mother tanks may also be referred to as source containers while the day tanks may also be referred to as dosing canisters.

The previously described multiple precursor dispensing unit 10 and auxiliary unit 200 are be used to support the tool's fluidic processor 300. The combination day tank 306 and manifold 308 communicate with the precursor chemical product line 54. The combination day tank 310 and manifold 312 communicate with the precursor chemical product line 56. The combination solvent day tank 314 and manifold 316 communicate with the shared solvent supply line 204, providing a common solvent sub-system between the interconnected dispenser, auxiliary, and tool units. The common waste line 114 supports a common waste sub-system between all three units. As previously described, the common waste line 114 also communicates with the vent 226 and vacuum 228 lines of the auxiliary unit 200 to provide a shared vacuum sub-system. Thus, the fluidic processor of the tool requiring multiple precursors is supplied by a single, modular, optimized multi-precursor dispenser. In the arrangement just described, the tool's fluidic processor and dispenser are also supported by a single modular solvent and waste unit, alternatively housed separately or with the dispenser.

Typically, a metal-organic CVD or atomic layer deposition tool includes dosing canisters in close proximity to the process chambers, thereby allowing better control of precursor delivery. The previously described embodiments of the present invention adapt well to these tools, and further avoid redundant and expensive dosing canisters. However, in some embodiments, the dispenser 10 is adapted to include the dosing canisters 306, 310, 314 of the tool's fluidic processor 300. The dispenser enclosure 12 is configured to contain the tank-manifold combinations seen in FIG. 3 to continuously supply an outside target process tool or tools, while still providing a modular and integrated fluidic processor that shares solvent, waste, vacuum, and, for some embodiments, gas pressurizing sub-systems via the shared lines described herein.

The connecting lines in and between the blocks or sub-manifolds and various others parts of the dispenser 10, auxiliary unit 200, and fluidic processor 300 are designed to retain the chemicals described herein. For example, the lines may be made of high purity stainless steel tubing. The shut-off valves described herein may be spring-less diaphragm high purity valves, for example.

With reference to FIGS. 4A-4D, an integrated liquid delivery system 400 for multiple chemical products is shown schematically FIGS. 4A-4D represent a fully integrated system, though shown on separate drawing sheets for viewing clarity. The system 400 includes the previously described modular multiple dispenser 10 (see FIGS. 4B and 4D) connected to the modular auxiliary unit 200 via common solvent supply line 204 and common waste line 114. The system also includes the tool's fluidic processor 300 (see FIG. 4C) connected to the dispenser 10 via the common solvent supply line 204, the first precursor line 54, the second precursor line 56, and the common waste line 114. The dispenser 10 may be located proximate to the processor 300, such as in the clean room adjacent the tool, or at a substantial distance from the processor. The large volume chemical tanks, relative to the day tanks, allow flow rates of liquid product to be maintained over significant distances. The processor 300 is also connected to the auxiliary unit 200 (see FIG. 4A) via common solvent supply line 204 and common waste line 114. The processor 300 represents only a portion of the entire manufacturing tool (not shown), as other parts of the tool are known to one having skill in the art and not necessary for a complete description of the embodiments herein.

In operation, the integrated system 400 is controlled by a controller (not shown) having an algorithm, the controller directing communication between the several units and completing the integrated system. As previously described, the several units of the system communicate through various shared components. The controller and the different units, in any combination, having their shared components allow the integrated system to perform as a modular tool. The controller may be any of various controllers consistent with the teachings herein, and may be located in various places, including the dispenser 10 or the fluidic processor 300, for example. If the controller is located in or near the tool's fluidic processor 300, an interface is placed in the dispenser 10 for a user to change out tanks in the dispenser 10 or otherwise interface with the dispenser 10 or the auxiliary unit 200. The controller is adaptable to communicate with the various subsystems of the system 400 in such a way that the tanks are operable independently of one another, as previously suggested. Alternatively, if separate controllers are used in the tool and the dispenser, the controllers communicate with each other so that the tool knows when chemicals tanks are being exchanged and the dispenser known when the tool requires precursors.

Part of the control algorithm is a refilling algorithm in which directions are given to individually refill the precursor day tanks 306, 310 and the solvent day tank 314 located in the tool processor. The mother tanks 14, 16 of the dispenser 10 supply the precursor and the solvent supply tank 212 of the auxiliary unit 200 supplies the process solvents. With each day tank, refill is initiated by the appropriate liquid level control sensor installed on, or in, each of the day tanks. For example, the control sensor may by a LOW level indicator consistent with the other sensors described herein. The refill flow is maintained by the pressure difference between the set pressure in the mother tanks and the set pressure in each corresponding day tank, which are both automatically controlled. The required delta pressure is automatically chosen such that a quick refill is provided while, at the same time, the pressure in the day tank is not upset, especially when the product chemical is simultaneously being withdrawn from the day tank into the process line of the tool (and into the tool's injecting system).

The refill is stopped when the day tank liquid level indicator, such as a HIGH chemical level indicator, signals that the day tank is replete. The day tank sensors, for example, include internal sensors such as buoyancy, ultrasound, capacitance, and differential pressure, and external sensors such as ultrasound and optical. The day tank sensors may also be continuous or discrete.

The remaining amounts of precursors, or solvents, in the mother tanks are also monitored by the controller algorithm. The mother tanks may be monitored continuously or discretely. The mother tanks include, for example, external sensors such as weight scales and ultrasound sensors. The mother tanks may also include, for example, internal sensors such as those previously mentioned. When a mother tank sensor signals “low,” the tank exchange procedure is initiated. This procedure includes those known to one having skill in the art and consistent with the teachings herein.

The waste level in the waste tank 208 is monitored by the controller and the waste tank level control sensors 209, 211. The waste tank sensors are consistent with the teachings given herein. When the waste tank sensor indicate a “high” level, a waste tank exchange procedure is conducted in accordance with principles known to one having skill in the art and consistent with the teachings herein.

The embodiments of the multiple dispenser 10 described herein provide a modular, integrated multi-chemical fluidic processor for continuously supplying multiple precursors to a target process tool. As shown herein, the dispenser 10 may also be combined with other modules to provide a system for storing and delivering the precursors to a tool's fluidic processor, such that the manufacturing tool can successfully and continuously receive multiple precursors for the deposition of multiple compound laminates.

The above discussion is meant to be illustrative of the principles and various embodiments of the present invention. While the preferred embodiment of the invention and its method of use have been shown and described, modifications thereof can be made by one skilled in the art without departing from the teachings of the invention. The embodiments described herein are exemplary only, and are not limiting. Many variations and modifications of the invention and apparatus and methods disclosed herein are possible and are within the scope of the invention. Accordingly, the scope of protection is not limited by the description set out above, but is only limited by the claims which follow, that scope including all equivalents of the subject matter of the claims

What is claimed is:

1. An apparatus for dispensing multiple precursors to a manufacturing tool comprising:
a fluidic manifold having a plurality of interconnected sub-manifolds;
a plurality of tanks, each tank containing a different precursor; and
wherein each of said sub-manifolds is connected to one of said tanks.

2. The apparatus of claim 1 wherein said fluidic manifold further includes a precursor sub-manifold connected to each of said plurality of tanks, said precursor sub-manifolds being interconnected.

3. The apparatus of claim 2 wherein said precursor sub-manifolds are interconnected by at least any one of a shared solvent supply line and a shared waste line.

4. The apparatus of claim 2 wherein said fluidic manifold further includes a pressurizing gas sub-manifold connected to each of said precursor sub-manifolds, said pressurizing gas sub-manifolds being interconnected.

5. The apparatus of claim 4 wherein said pressurizing gas sub-manifolds are interconnected by at least a common vent line.

6. The apparatus of claim 2 wherein said fluidic manifold further includes a single pressurizing gas sub-manifold connected to each of said precursor sub-manifolds.

7. The apparatus of claim 1 wherein said plurality of tanks includes source containers substantially larger than a dosing canister of a fluidic processor of the manufacturing tool.

8. The apparatus of claim 1 further comprising an auxiliary unit including:
a waste tank to receive waste from said interconnected sub-manifolds; and
a solvent tank to supply solvent to said interconnected sub-manifolds.

9. The apparatus of claim 8 wherein said waste tank is also to receive waste from a fluidic processor of the manufacturing tool via a waste line shared with said interconnected sub-manifolds and said solvent tank is also to supply solvent to said fluidic processor via a solvent supply line shared with said interconnected sub-manifolds.

10. The apparatus of claim 1 wherein each of said tanks includes at least one level sensor.

11. The apparatus of claim 10 wherein each of said tanks includes a plurality of liquid level sensors comprising a LOW sensor, a LOW-LOW sensor and a HIGH sensor.

12. The apparatus of claim 1 further comprising a controller to communicate with said fluidic manifold and each of said plurality of tanks.

13. The apparatus of claim 12 wherein said controller communicates with each of the sub-manifold and tank combinations such that each of said tanks is operable independent of any other of said tanks.

14. A method of dispensing multiple precursors to a manufacturing tool comprising:
providing a fluidic manifold and a plurality of tanks, each tank containing a different precursor, wherein said fluidic manifold further includes a plurality of interconnected sub-manifolds with each of said sub-manifolds connected to one of said tanks;
detecting a low precursor level in a fluidic processor of the manufacturing tool; and
dispensing a precursor from one of said tanks independently of any other of said tanks.

15. The method of claim 14 further comprising purging a fluid from said interconnected sub-manifolds via a shared line.

16. The method of claim 14 further comprising supplying a fluid to said interconnected sub-manifolds via a shared supply line.

17. The method of claim 15 further comprising:
communicating waste gases from a plurality of interconnected pressurizing gas sub-manifolds to a shared vent line; and
communicating waste liquids from a plurality of interconnected precursor sub-manifolds to an auxiliary unit via a shared waste line.

18. The method of claim 16 further comprising supplying a solvent to a plurality of interconnected precursor sub-manifolds from an auxiliary unit via a shared solvent line.

19. The method of claim 14 further comprising communicating waste from said fluidic processor of the manufacturing tool to said fluidic manifold to an auxiliary unit via a commonly shared waste line.

20. The method of claim 19 further comprising detecting a high level of said waste and exchanging a waste tank.

21. The method of claim 14 further comprising supplying a solvent from an auxiliary unit to any one of said fluidic manifold and said fluidic processor of the manufacturing tool via a commonly shared solvent line.

22. The method of claim 14 further comprising detecting a low level in at least one of said tanks and exchanging said low-level tank.

23. The method of claim 22 further comprising flushing the sub-manifold of said low-level tank with a solvent from an auxiliary unit before replacing said low-level tank.

24. The method of claim 14 further comprising continuously controlling said fluidic manifold and said tanks to supply said fluidic processor of the manufacturing tool with said plurality of different precursors.

25. A system for dispensing multiple precursors to a manufacturing tool comprising:
a multiple precursor dispenser having a fluidic manifold and a plurality of tanks, each tank containing a different precursor and connected to a different sub-manifold of said fluidic manifold, said sub-manifolds being interconnected;
a manufacturing tool fluidic processor having a plurality of canisters, each canister containing a different precursor;
wherein a first dispenser tank communicates with a first tool canister having the same precursor; and
wherein a second dispenser tank communicates with a second tool canister having the same precursor.

26. The system of claim 25 wherein said sub-manifolds are interconnected by any one of a shared vent line, a shared waste line, and a shared solvent line.

27. The system of claim 25 further comprising:
a first sub-manifold connected to said first dispenser tank and a shared waste line;
a second sub-manifold connected to said second dispenser tank a said shared waste line; and
wherein said first and second sub-manifolds communicate pressurizing gases to said dispenser tanks, receive precursors from said dispenser tanks, and communicate waste to said shared waste line.

28. The system of claim 27 further comprising a shared solvent line connected to both of said first and second sub-manifolds.

29. The system of claim 27 further including a pressurizing gas sub-manifold connected to each of said first and second sub-manifolds, said pressurizing gas sub-manifolds interconnected by a shared vent line.

30. The system of claim 25 further comprising an auxiliary unit including any one of.
a waste tank to receive waste from said dispenser and said manufacturing tool fluidic processor via a waste line commonly shared with said interconnected sub-manifolds; and
a solvent tank to supply solvent to said dispenser and said manufacturing tool fluidic processor via a solvent line commonly shared with said interconnected sub-manifolds.

31. The system of claim 25 further comprising:
at least one level sensor on all of said tanks; and
a controller communicating with all of said sensors to operate each of said tanks independently of any other of said tanks.

32. A method of dispensing multiple precursors to a manufacturing tool comprising:
providing a manufacturing tool having a fluidic processor with multiple precursor canisters;
providing a multiple precursor dispenser connected to said tool, said dispenser having a fluidic manifold with interconnected sub-manifolds and a plurality of tanks;
detecting a low precursor level in the manufacturing tool;
dispensing a first precursor from said dispenser to said tool; and
further dispensing a second precursor from said dispenser to said tool.

33. The method of claim 32 further comprising:
continuously dispensing a plurality of precursors from said dispenser to said tool and dispensing each precursor independently of any other precursor.

34. The method of claim 33 further comprising.
simultaneously with dispensing a first precursor from said dispenser to said tool, disconnecting a tank containing said second precursor from said dispenser; and
replacing said tank.

35. The method of claim 32 further comprising purging a fluid from said interconnected sub-manifolds via a shared line.

36. The method of claim 35 further comprising:
communicating wastes gases from a plurality of interconnected pressurizing gas sub-manifolds via a shared vent line; and
communicating waste liquids from a plurality of interconnected precursor sub-manifolds and said tool to an auxiliary unit via a commonly shared waste line.

37. The method of claim 32 further comprising supplying a fluid to said interconnected sub-manifolds via a shared line.

38. The method of claim 37 further comprising communicating solvent from an auxiliary unit to a plurality of interconnected precursor sub-manifolds and said tool via a commonly shared solvent supply line.
